(19) United States
(12) Patent Application Publication
(10) Pub. No.: US 2024/0274771 A1
(43) Pub. Date: Aug. 15, 2024

(54) OPTOELECTRONIC LIGHTING DEVICE

(71) Applicant: ams-OSRAM International GmbH, Regensburg (DE)

(72) Inventors: Sebastian WITTMANN, Regenstauf (DE); Michael BRANDL, Mintraching (DE); Uli HILLER, Abbach (DE); Andreas DOBNER, Wenzenbach (DE)

(21) Appl. No.: 18/565,453

(22) PCT Filed: May 30, 2022
(86) PCT No.: PCT/EP2022/064630

§ 371 Date: Nov. 29, 2023

(30) Foreign Application Priority Data
May 31, 2021 (DE) 10 2021 114 070.6

(51) Int. Cl. H01L 33/62; H01L 25/075; H01L 33/56; H01L 33/60

(52) U.S. Cl. CPC H01L 33/62; H01L 25/0753; H01L 33/56; H01L 33/60

(57) ABSTRACT

An optoelectronic lighting device includes an at least partially transparent base body with a first main surface that is, in particular curved surface, and a second main surface. The second main surface does at least partially not extend parallel to the first main surface. A decorative layer is arranged on the curved first main surface, which substantially follows the curvature of the first main surface. An optoelectronic foil is arranged on the second main surface. The optoelectronic foil includes a carrier substrate that is, in particular a flexible carrier substrate; at least one electrical line and a plurality of optoelectronic semiconductor components arranged on the carrier substrate; and an at least partially transparent adhesive layer, which is arranged between the optoelectronic semiconductor components and the base body and which connects the optoelectronic foil to the second main surface. The optoelectronic semiconductor components are embedded in the adhesive layer.

The present application claims the priority of German patent application No. 10 2021 114 070.6 of May 31, 2021, the disclosure of which is hereby incorporated by reference into the present application.

The present invention deals with technologies for the illumination of decorative parts, in particular plastic decorative parts, of, for example, household appliances, consumer products, or decorative parts in motor vehicles. Furthermore, the present invention deals with technologies for displaying information on decorative parts, in particular plastic decorative parts, of, for example, household appliances, consumer products, or on decorative parts in motor vehicles. In particular, the invention relates to an optoelectronic lighting device comprising an at least partially transparent base body on the rear side of which optoelectronic semiconductor components are arranged in order to illuminate the base body or to display information on the base body.

### BACKGROUND

At present, one or more lighting devices, consisting of LEDs mounted on a PCB board, are mounted behind the decorative part for the illumination of decorative parts. In addition to the LEDs, the PCB board and a mounting for the lighting device, light-forming elements are often also required. This results in a required installation depth of typically 10 mm to 30 mm.

In addition to such a large construction depth, it is also difficult to realize shapes that go beyond the two-dimensional with the known solutions. Although this can be solved with several independent lighting devices mounted behind the trim piece, this increases the manufacturing and assembly costs and the weight of the trim piece also increases with the number of lighting devices required.

There is therefore a need to counteract the aforementioned problems and to provide an illuminated decorative part or a means of backlighting a decorative part in a simple and cost-effective way.

### SUMMARY OF THE INVENTION

This and other needs are met by an optoelectronic lighting device with the features of claim 1. Embodiments and further embodiments of the invention are described in the dependent claims.

An optoelectronic lighting device according to the invention comprises a base body which is at least partially transparent and has a curved first main surface and second main surface. The second main surface lies opposite the first main surface and does not run parallel to it, at least in some areas. The optoelectronic lighting device further comprises a decorative layer arranged on the curved first main surface, which substantially follows the curvature of the first main surface. In addition to this, an optoelectronic foil is arranged on the second main surface, which has a particularly flexible carrier substrate, at least one electrical line and a plurality of optoelectronic semiconductor components. The at least one electrical line and the plurality of optoelectronic semiconductor components are arranged on the carrier substrate. Furthermore, the optoelectronic foil has an at least partially transparent adhesive layer which is arranged between the optoelectronic semiconductor components and the base body and which connects the optoelectronic foil to the second main surface.

The core of the invention is to integrate optoelectronic semiconductor components into a foil which has electrical contacts or lines in order to supply the optoelectronic semiconductor components with energy or to control them. This foil is applied to the back of a decorative part, whereby the decorative part is designed in such a way that it has more and less transparent areas. In particular, the transparent areas are geometrically aligned with the optoelectronic semiconductor components. This means that the decorative part can be backlit without the space- and weight-intensive approach described above, in which discrete PCB boards with LEDs mounted on them are used. The optoelectronic foil and, in particular, the carrier substrate can be designed to be flexible so that it can be applied to the back of the decorative part in accordance with the shape and design of the latter.

In some embodiments, a number of the plurality of optoelectronic semiconductor components are arranged in front of at least one transparent area of the base body, as viewed in an emission direction of an optoelectronic semiconductor component. Thus, the base body can be backlit, in particular in the transparent areas, thereby creating a desired optical impression of the base body or the decorative part.

The optoelectronic semiconductor components can each be formed by a lighting element or an LED. In some embodiments, each of the light emitting elements forms a light spot, wherein the totality of the light spots backlight the base body in a desired manner during an intended use of the optoelectronic lighting device. The light points can be arranged randomly in relation to one another, arranged in a desired pattern or matrix, or they can, for example, only be arranged in areas behind the base body that are to be illuminated during intended use of the optoelectronic lighting device.

In some embodiments, at least one of the plurality of optoelectronic semiconductor components may be formed by a light emitting element or LED comprising a conversion material. For example, the conversion material may be disposed over a light emitting region of the semiconductor component and configured to convert the light emitted by the semiconductor component into light of a different wavelength.

In some embodiments, each of the plurality of optoelectronic semiconductor components is formed by an LED, in particular an LED chip. In particular, an LED may be referred to as a mini-LED. A mini-LED is a small LED, for example with edge lengths of less than 200 μm, in particular up to less than 40 μm, in particular in the range of 200 μm to 10 μm. Another range is between 150 μm and 40 μm. At these spatial dimensions, the optoelectronic semiconductor component is almost invisible to the human eye.

The LED may also be referred to as a micro LED, also known as a μLED, or a μLED chip, particularly in the case where the edge lengths are in the range of 100 μm to 10 μm. In some embodiments, the LED may have a spatial dimension of 90×150 μm or a spatial dimension of 75×125 μm.

In some embodiments, the mini LED or μLED chip can be an unhoused semiconductor chip. Unhoused means that the chip does not have a package around its semiconductor layers, such as a “chip die”. In some embodiments, unhoused may mean that the chip is free of any organic material. Thus, the unhoused device does not contain any organic compounds that contain carbon in covalent bonding.

In some embodiments, each of the plurality of optoelectronic semiconductor components is formed by a surface-emitting optoelectronic semiconductor component. In particular, such a surface-emitting optoelectronic semiconductor component may be formed as a flip chip and arranged on the carrier substrate of the optoelectronic foil such that the light-emitting surface of the optoelectronic semiconductor components faces towards the base body.

However, each of the plurality of optoelectronic semiconductor components may also be formed by a volume-emitting optoelectronic semiconductor component or an edge-emitting optoelectronic semiconductor component. In particular, each of the plurality of optoelectronic semiconductor components may be formed and arranged on the carrier substrate of the optoelectronic foil such that the optoelectronic semiconductor components emit light along the main propagation direction of the optoelectronic foil. In particular, such a semiconductor component can also be referred to as a side-looking emitter.

In some embodiments, each of the plurality of optoelectronic semiconductor components is formed by a sapphire flip chip, a flip chip emitting light through its side faces, a surface emitter, a volume emitter, an edge emitter, or by a horizontally emitting μLED chip.

In some embodiments, each of the plurality of semiconductor optoelectronic devices may comprise a mini-LED or μLED chip configured to emit light of a selected color. In some embodiments, two or more of the plurality of semiconductor optoelectronic devices may form a pixel, such as an RGB pixel comprising three mini-LEDs or μLED chips. For example, an RGB pixel can emit light of the colors red, green and blue as well as any mixed colors. In some embodiments, more than three of the plurality of optoelectronic semiconductor components may also form a pixel, such as an RGBW pixel comprising four mini-LEDs or μLED chips. An RGBW pixel can, for example, emit light of the colors red, green, blue and white as well as any mixed colors. For example, white light or red light or green light or blue light can be generated in the form of a full conversion using an RGBW pixel.

In some embodiments, each of the plurality of optoelectronic semiconductor components is associated with an integrated circuit for driving the same. In some embodiments, two or more of the plurality of optoelectronic semiconductor components are each associated with an integrated circuit for driving them. For example, one RGB pixel may be assigned to an integrated circuit (IC). The integrated circuit or integrated circuits may, for example, be formed by a particularly small integrated circuit, such as a micro-integrated circuit (μIC).

In some embodiments, the second main surface is flat and has no curvature. This makes it possible to attach the optoelectronic foil to the base body in a simple manner.

In some embodiments, the second main surface also has a curvature in at least one spatial direction. For example, the second main surface may have a curvature in exactly one spatial direction. In particular, the second main surface can comprise several subregions that are flat, and the subregions can be tilted or rotated relative to one another by at most one spatial direction. The angle of the tilt can usually be less than 90°. This makes it possible for the optoelectronic foil to be laminated onto the base body simply and only by deforming or bending the foil about this one spatial direction.

In some embodiments, the optoelectronic foil substantially follows the curvature of the second main surface. In particular, the optoelectronic foil extends substantially parallel to the second major surface and accordingly abuts the second major surface over the entire second major surface.

In some embodiments, the optoelectronic foil is formed by at least two sub-foils. A first sub-foil is arranged on a first partial region of the second main surface and a second sub-foil is arranged on a second partial region of the second main surface. In particular, the first and second partial regions of the second main surface can each be flat partial regions on which the partial foils are formed. The optoelectronic foil can be cut up accordingly and the resulting partial foils can each be arranged on the flatly formed partial regions of the second main surface.

In some embodiments, the decorative layer has at least partial regions that are transparent. In particular, partial regions of the decorative layer can be transparent, which are to be illuminated during intended use of the optoelectronic lighting device. In the following, we can therefore also refer to a semi-transparent decorative layer, since only areas of the decorative layer can be translucent for the light emitted by the optoelectronic semiconductor components.

The decorative layer can, for example, be formed from a sequence of layers. The layer sequence can, for example, comprise a transparent or diffuse carrier layer and a protective layer arranged above the carrier layer. Furthermore, the backing layer can have a coating on the side facing the protective layer and/or on the side facing away from the protective layer, each of which comprises translucent and opaque or light-absorbing areas. In particular, the sequence of layers can be arranged on the first main surface in such a way that the protective layer faces away from the first main surface.

The decorative layer or layers of the decorative layer can be formed, for example, by at least one of the following materials:
a polymer foil;
a thin layer of wood;
a layer with a wood look;
real wood;
a printed varnish layer;
textiles;
metal foils, e.g. aluminum foil;
carbon fiber mats or foils;
printed plastic foils;
a thin leather;
imitation leather;
a leather-look foil; and
a plastic foil with a metal look.

In some embodiments, the optoelectronic semiconductor components are embedded or encapsulated in the adhesive layer. In particular, the optoelectronic semiconductor components may be bonded to the carrier substrate and potted with the adhesive layer and thus embedded therein. Similarly, the at least one electrical line can also be embedded or cast in the adhesive layer.

In some embodiments, the at least one electrical line is arranged on the carrier substrate and then the optoelectronic semiconductor components are applied to the resulting electrical contact points. The at least one electrical line can thus be arranged between the carrier substrate and the optoelectronic semiconductor components. However, the optoelectronic semiconductor components can also be arranged on the carrier substrate first and the at least one electrical line can then be applied to the optoelectronic semiconductor components for contacting the optoelectronic semiconductor components. The at least one electrical line can thus be arranged at least partially on the optoelectronic semiconductor components.

In some embodiments, the adhesive layer comprises at least one of the following materials:
PVB;
EVA;
Silicone;
Acrylic;
pressure sensitive adhesives;
melting cements; and
an epoxy.

In particular, the adhesive layer can have adhesive properties so that the optoelectronic foil can be attached to the second main surface by means of the adhesive layer.

In some embodiments, the adhesive layer is provided with light-absorbing particles. In particular, the adhesive layer can be provided with black particles, such as aluminum or other metal particles, in order to achieve a higher contrast and lower bleeding of the optoelectronic lighting device.

In some embodiments, the optoelectronic lighting device comprises a protective foil covering a side of the optoelectronic foil opposite the base body. In particular, the protective foil may enclose the optoelectronic foil and serve as corrosion protection for the foil. The protective foil can, for example, enclose the optoelectronic foil and also be formed in areas on the second main surface that are not covered by the optoelectronic foil.

In some embodiments, at least one of the base body, the decorative layer and the adhesive layer has light-scattering particles. For example, the decorative layer and/or the base body can have at least areas in which light-scattering particles are arranged. In this way, for example, a homogeneous impression of the illuminated areas of the optoelectronic lighting device can be achieved. It is also possible for the adhesive layer to have at least areas that contain light-scattering particles. This makes it possible, for example, to achieve homogeneous back-lighting of the base body.

In addition to the light-scattering effect, the light-scattering particles can also be suitable for creating a white impression of the optoelectronic lighting device. For example, it may be desirable to create a white impression over the entire illuminated area of the optoelectronic lighting device, or it may also be desirable, for example, for only certain illuminated areas of the optoelectronic lighting device to have a white impression. A white impression can be achieved, for example, by light-scattering particles that comprise, for example, aluminum oxide (AlO₂₃) and/or titanium oxide (TiO).₂

In some embodiments, at least one of the base body, the decorative layer and the adhesive layer has light-converting particles. For example, the decorative layer and/or the base body and/or the adhesive layer may have at least regions in which light-converting particles are arranged. As a result, for example, light of a first wavelength emitted by an optoelectronic semiconductor component can be converted into light of a second wavelength that differs from the first wavelength. In some embodiments, at least one of the base body, the decorative layer and the adhesive layer has at least two different types of light-converting particles. As a result, for example, light of a first wavelength and light of a second wavelength emitted by two optoelectronic semiconductor components can be converted into light of a third and fourth wavelength. The first, second, third and fourth wavelengths can differ from each other.

In some embodiments, the adhesive layer comprises a layer sequence of a first sublayer and a functional sublayer. The first sublayer can, for example, be formed by a material that has adhesive properties. The functional sublayer can be designed to add a further functional property to the adhesive layer in addition to the adhesive properties.

In some embodiments, the optoelectronic semiconductor components are encapsulated in the functional sublayer. For example, the functional layer can be in the form of an anti-corrosion layer and thus protect the optoelectronic semiconductor components embedded in the functional sublayer from corrosion.

In some embodiments, the optoelectronic semiconductor components are molded into the first sublayer.

In some embodiments, the functional sublayer is arranged adjacent to the base body. For example, the functional layer may take the form of a coating of the first sublayer and thus be arranged between the base body and the first sublayer.

In some embodiments, the adhesive layer comprises a second sublayer. In particular, in this case the functional sublayer may be arranged between the first and second sublayers. The first and second sublayers may, for example, be formed from the same material, the material having adhesive properties in particular.

In some embodiments, the entire functional sublayer comprises light-converting and/or light-scattering particles and in some embodiments, the functional sublayer comprises at least partial regions in which light-converting and/or light-scattering particles are arranged. For example, the functional sublayer may comprise regions in which light-converting particles are arranged. This allows, for example, light of a first wavelength emitted by an optoelectronic semiconductor component to be converted into light of a second wavelength that differs from the first wavelength. Alternatively or additionally, the functional sublayer can have areas in which light-scattering particles are arranged. This makes it possible, for example, to achieve homogeneous backlighting of the base body. As already explained above, the light-scattering particles can also be suitable for creating a white impression of the optoelectronic lighting device in addition to the light-scattering effect.

In some embodiments, the functional sublayer comprises at least a second subregion in which light-absorbing particles are arranged. For example, the functional sublayer can be structured and comprise at least a first partial region that is designed to be translucent and at least a second partial region that has light-absorbing particles and is thus at least partially designed to be light-absorbing or opaque. The contrast of the optoelectronic lighting device can, for example, be increased by the structuring or the partial regions that have light-absorbing particles.

In some embodiments, the optoelectronic lighting device additionally comprises a reflector layer which is arranged on a side of the carrier substrate opposite the base body. The reflector layer can, for example, be designed to reflect the light emitted by the optoelectronic semiconductor components, which is not emitted in the direction of the base body, in the direction of the base body. For example, the reflector layer can be formed by a white coating of the carrier substrate.

In some embodiments, the reflector layer is structured in such a way that it only covers the areas of the carrier substrate opposite the optoelectronic semiconductor components. Accordingly, the reflector layer can be arranged on the carrier substrate only below the optoelectronic semiconductor components.

In some embodiments, the structured reflector layer has light-absorbing areas. In particular, the reflector layer can have areas that are designed to be reflective and have recesses that are filled with a light-absorbing material. The reflective areas can be arranged below the optoelectronic semiconductor components on the carrier substrate and the remaining areas on the carrier substrate can be covered with the light-absorbing material or the corresponding recesses in the reflector layer can be filled with the light-absorbing material.

In some embodiments, at least one of the base body and the adhesive layer has micro-structured optics. In particular, the micro-structured optics are arranged in the beam path of the optoelectronic semiconductor components. For example, the micro-structured optics can be formed by lenses that are embedded in the base body and/or the adhesive layer. In particular, the micro-structured optics may be formed by a material with a high refractive index, in particular by a material with a higher refractive index than the material adjacent to the micro-structured optics. In some embodiments, at least one micro structured optic may extend from the adhesive layer into the base body.

The micro-structured optics can, for example, be designed to focus, disperse or direct the light emitted by the optoelectronic semiconductor components. In particular, the microstructured optics can, for example, be designed to direct the light emitted by the optoelectronic semiconductor components in the direction of the transparent areas of the base body and/or in the direction of the transparent areas of the decorative layer.

In some embodiments, at least one of the base body and the adhesive layer has at least one cavity filled with air and/or at least one hollow space filled with air. The at least one cavity and/or the at least one hollow space are designed and arranged in such a way that they form an optical element, in particular a lens, in the beam path of at least one optoelectronic semiconductor component. For example, at least one cavity filled with air in the form of a thickened conical surface can be formed in the base body, which acts as a lens, in particular as a lens with total internal reflection (TIR). Further exemplary embodiments are explained in this respect in the detailed description.

In some embodiments, the decorative layer is formed by a light-absorbing material and has recesses. In particular, the recesses in the present case act as the “transparent” areas of the decorative layer through which the light from the optoelectronic semiconductor components passes to the outside. The recesses in the decorative layer thus define the areas that are to be illuminated during intended use of the optoelectronic lighting device.

The recesses can remain free, i.e. not filled with any material, but in some embodiments the recesses of the decorative layer are filled with a transparent material.

In some embodiments, the recesses of the decorative layer are filled with a material comprising light-scattering and/or light-converting particles. The advantages and embodiments of the material filled with light-scattering and/or light-converting particles may correspond to the advantages and embodiments already described above.

In some embodiments, an optical element, in particular a lens, is arranged in at least one of the recesses. Such a lens may, for example, have been produced by means of a 3D coating and serve to focus, disperse or direct the light of the optoelectronic semiconductor components emerging from the recesses of the decorative layer.

In some embodiments, the decorative layer comprises a reflective layer that is formed adjacent to the base body. The recesses can also extend through the reflective layer. Such a reflective layer can be advantageous in order to give the luminous impression of the optoelectronic lighting device a higher contrast. Furthermore, the reflective layer can be used to give the decorative layer a reflective or mirror-like or metallic effect on the outside. The reflective layer can be made of a white or black material, for example.

In some embodiments, a light guide is formed in at least one of the base body and the adhesive layer. Such a light guide can, for example, be printed onto the carrier substrate, for example by screen or stencil printing, spraying, molding, dispensing or jetting, and cast in the adhesive layer. At least one optoelectronic semiconductor component can be embedded in the light guide so that the light emitted by the at least one optoelectronic semiconductor component can be distributed along the light guide. For example, several optoelectronic semiconductor components can also be connected by means of an optical fiber and form an additional symbol within a matrix arrangement of several optoelectronic semiconductor components. It is also conceivable that areas emitting area and point light can be realized simultaneously within a matrix arrangement of several optoelectronic semiconductor components. Furthermore, such a light guide can also enable light to be directed into an area of the optoelectronic lighting device in which no optoelectronic semiconductor components are arranged on the carrier substrate. In some embodiments, several such light guides can also be used to display fine, precise lines that can be controlled independently of one another.

In some embodiments, the carrier substrate has a structured area so that light emitted by an edge- or volume-emitting semiconductor chip is directed towards the base body. For example, the carrier substrate and/or the adhesive layer can be designed as a light guide into which the light from the optoelectronic semiconductor components is coupled. Furthermore, the carrier substrate can have a structured area so that the light guided along the carrier substrate is directed towards the base body at the structured area.

In some embodiments, at least a number of the plurality of optoelectronic semiconductor components are arranged in a matrix of rows and columns on the carrier substrate. Furthermore, the optoelectronic semiconductor components arranged in the matrix may be individually controllable. The optoelectronic semiconductor components arranged in the matrix can accordingly be designed as a display or a mini-display, which is formed in the optoelectronic lighting device.

### BRIEF DESCRIPTION OF THE DRAWINGS

In the following, embodiments of the invention are explained in more detail with reference to the accompanying drawings. They show, in each case schematically,

FIG. 1 a sectional view of an optoelectronic lighting device and a detailed view of a decorative layer according to some aspects of the proposed principle;

FIG. 2 to FIG. 13 sectional views of further embodiments of an optoelectronic lighting device according to some aspects of the proposed principle;

FIGS. 14A and 14B a sectional view and a plan view of an embodiment of an optoelectronic lighting device comprising an optical element formed by cavities and cavities according to some aspects of the proposed principle;

FIGS. 15 to 19 sectional views of further embodiments of an optoelectronic lighting device according to some aspects of the proposed principle;

FIGS. 20A and 20B a sectional view and a plan view of an embodiment of an optoelectronic lighting device comprising a light guide according to some aspects of the proposed principle;

FIGS. 21 to 23 sectional views of further embodiments of an optoelectronic lighting device according to some aspects of the proposed principle;

FIGS. 24A and 24B a sectional view and a plan view of an embodiment of an optoelectronic lighting device comprising an edge-emitting semiconductor chip according to some aspects of the proposed principle;

FIGS. 25A and 25B a sectional view and a plan view of another embodiment of an optoelectronic lighting device comprising an edge-emitting semiconductor chip according to some aspects of the proposed principle;

FIGS. 26A and 26B a sectional view and a plan view of an embodiment of an optoelectronic lighting device comprising a patterned decorative layer according to some aspects of the proposed principle;

FIG. 27 a sectional view of a further embodiment of an optoelectronic lighting device comprising a structured decorative layer according to some aspects of the proposed principle;

FIGS. 28 and 29 each a sectional view of an embodiment of an optoelectronic lighting device in which the second main surface has a curvature in at least one spatial direction, according to some aspects of the proposed principle;

FIG. 30 a top view of an optoelectronic foil according to some aspects of the proposed principle; and

FIGS. 31A and 31B a plan view and a sectional view of an optoelectronic lighting device comprising a matrix array of semiconductor optoelectronic devices according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

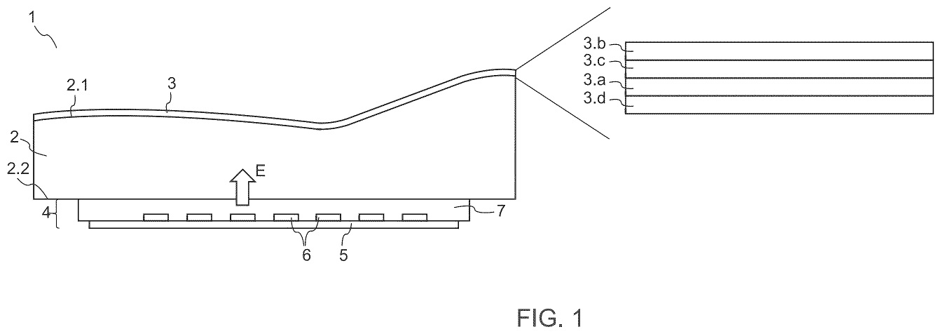

FIG. 1 shows a sectional view of an optoelectronic lighting device (1) according to some aspects of the proposed principle. The optoelectronic lighting device (1) comprises a base body (2) which is at least partially transparent and has a curved first main surface (2.1) and a second main surface (2.2) opposite the first main surface (2.1). The curvature of the first main surface (2.1) essentially corresponds to an outer contour of the optoelectronic lighting device (1). In contrast, the second main surface (2.2) is flat in the present example and does not run parallel to the first main surface (2.1), at least in some areas. The base body (2) has different thicknesses corresponding to the curvature of the first main surface (2.1). A decorative layer (3) is arranged on the first main surface (2.1), which has a substantially uniform thickness and which follows the curvature of the first main surface (2.1). The decorative layer (3) can have a sequence of layers, as shown on the right in the figure, and can comprise, for example, a transparent or diffuse backing layer (3.a) and a protective layer (3.b) arranged over the backing layer (3.a). Furthermore, in the illustrated embodiment example, a first coating (3.c) is formed on a side of the carrier layer (3.a) facing the protective layer (3.b) and a second coating (3.d) is formed on a side of the carrier layer (3.a) facing away from the protective layer (3.b). The first coating (3.c) and the second coating (3.b) can, for example, be printed on the carrier layer (3.a) and each have light-transmitting and light-impermeable partial regions. The translucent and opaque partial regions can be designed in such a way that they define the areas that are to be illuminated during intended use of the optoelectronic lighting device. For example, a corresponding pattern of translucent subregions can be generated in this way, which should light up during intended use of the optoelectronic lighting device.

An optoelectronic foil (4) is arranged on the second main surface (2.2), which is designed to backlight the base body (2) and the decorative layer (3). The optoelectronic foil (4) has a particularly flexible carrier substrate (5), as well as at least one electrical line arranged on the carrier substrate (5) and a plurality of optoelectronic semiconductor components (6). Furthermore, the optoelectronic foil (4) has an at least partially transparent adhesive layer (7), which is arranged between the optoelectronic semiconductor components (6) and the base body (2). The adhesive layer (7) is designed in particular to bond the optoelectronic foil (4) to the second main surface (2.2) and has adhesive properties for this purpose.

The optoelectronic semiconductor components (6) are arranged on the carrier substrate (5) or the optoelectronic foil (4) is arranged on the second main surface (2.2) in such a way that the transparent areas of the base body (2) lie in the direction of emission (E) or in the beam path of the optoelectronic semiconductor components (6). Thus, the optoelectronic semiconductor components (6) arranged in the optoelectronic foil (4) can backlight the base body (2) and the decorative layer (3) and, in particular, the transparent or translucent areas of the base body (2) and the decorative layer (3), thereby creating a desired optical impression of the base body (2) or the optoelectronic lighting device (1).

In the present case, the optoelectronic semiconductor components (6) are designed as surface-emitting semiconductor chips, in particular as surface-emitting flip chips, and emit light predominantly from the surface of the semiconductor chips opposite the carrier substrate (5) in the direction of emission (E). The optoelectronic semiconductor components (6) are embedded in the adhesive layer (7) and are supplied with electrical energy or controlled by means of at least one electrical line arranged on the carrier substrate (5).

The optoelectronic semiconductor components (6) can be formed in particular by very small semiconductor chips, in particular by very small unhoused semiconductor chips, so that the optoelectronic foil (4) can be particularly thin. This has the advantage that the optoelectronic foil (4) can be applied to the second main surface (2.2) over a large area and in a cost-effective manner, for example by rolling.

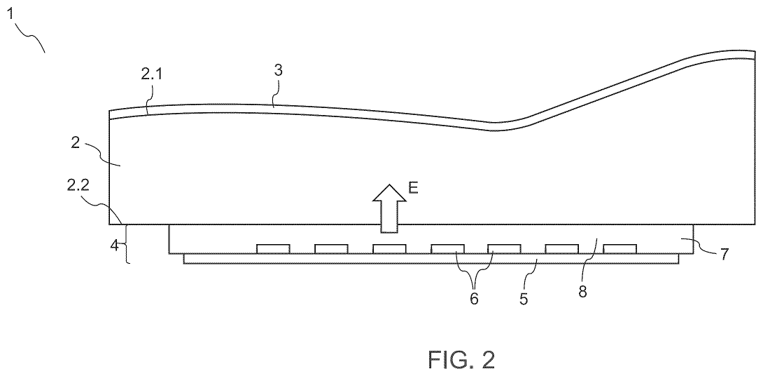

FIG. 2 shows a sectional view of a further optoelectronic lighting device (1), which has an essentially identical structure to the optoelectronic lighting device (1) shown in FIG. 1. In contrast to the optoelectronic lighting device (1) shown in FIG. 1, however, the adhesive layer (7) comprises light-absorbing particles (8), albeit in a low concentration. The adhesive layer (7) can, for example, be designed similarly to a tinted pane or a sun protection foil. Despite the light-absorbing particles (8), the adhesive layer (7) is at least partially transparent due to the low concentration of light-absorbing particles (8), so that at least the light emitted by the optoelectronic semiconductor components (6) can pass through the adhesive layer (7). The advantage of an adhesive layer (7) comprising light-absorbing particles (8) is that the contrast of the light emitted by the optoelectronic semiconductor components (6) can be increased and a so-called bleeding effect can be reduced.

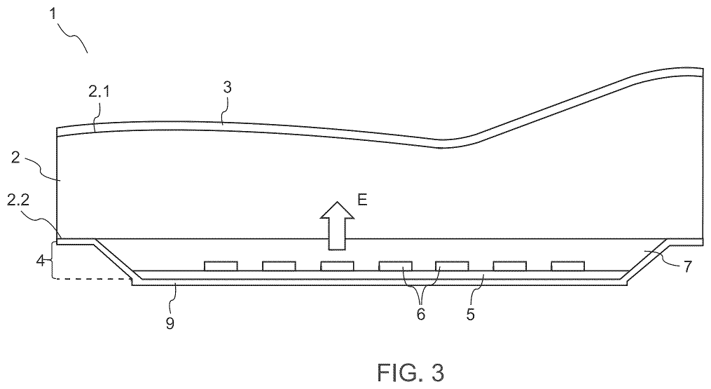

The optoelectronic lighting device (1) shown in FIG. 3 has, in addition to the optoelectronic lighting device (1) shown in FIG. 1, a protective foil (9) which covers one side of the optoelectronic foil (4) opposite the base body (2). The protective foil (9) can, for example, enclose the optoelectronic foil (4) and can serve as corrosion protection for the foil (4). As shown in the figure, the protective foil (9) also covers areas of the second main surface (2.2) that are not covered by the optoelectronic foil (4). The protective foil (9) is designed in particular as a coating of the optoelectronic foil (4) and the second main surface (2.2). For example, the protective foil (9) can be printed, laminated or sprayed onto the optoelectronic foil (4) or the second main surface (2.2). The protective foil (9) can, for example, protect the optoelectronic foil (4) from external influences or the heat generated by the optoelectronic semiconductor components (6) can be better dissipated by means of the protective foil (9).

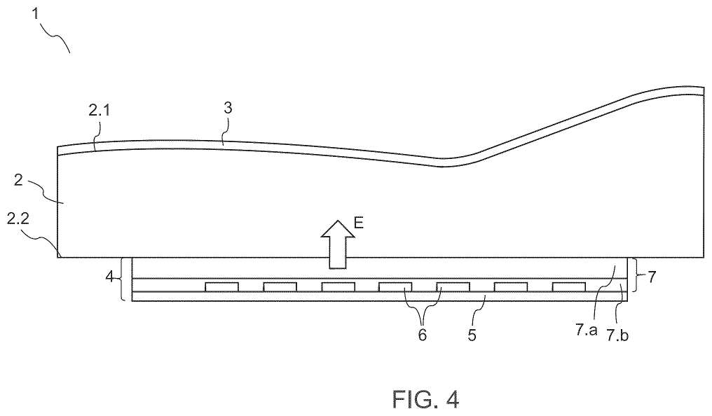

As shown in FIG. 4, the adhesive layer (7) can consist of a sequence of layers. In the illustrated embodiment example, the layer sequence of the adhesive layer (7) has a first sublayer (7.a) and a functional sublayer (7.b). The first sublayer (7.a) can be formed in accordance with the embodiment examples described above and, in particular, have adhesive properties. The functional sublayer (7.b), on the other hand, has a further functional property in addition to the adhesive properties and in the present case is designed as an anti-corrosion layer. The optoelectronic semiconductor components (6) are embedded in the functional sublayer (7.b) and are thus protected against corrosion. The functional sublayer (7.b) can, for example, be printed, laminated or sprayed on.

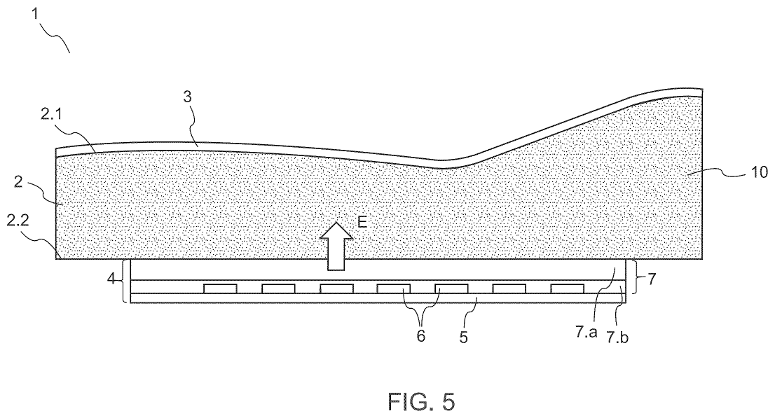

At least one or more of the base body (2), the decorative layer (3) and the adhesive layer (7) can have areas in which light-scattering particles are arranged. In this way, for example, a homogeneous impression of the illuminated areas of the optoelectronic lighting device can be achieved. FIG. 5 shows by way of example that the base body (2) has light-scattering particles (10). Due to the light-scattering particles (10) arranged in the base body (2), the light emitted by the optoelectronic semiconductor components (6) in the direction of the base body (2) can be scattered within the base body (2) so that the decorative layer (3) is homogeneously backlit. As a result, translucent areas of the decorative layer (3) can be evenly illuminated. However, it is also possible that, alternatively or additionally, the decorative layer (3) and/or the adhesive layer (7) has at least areas that comprise light-scattering particles (10).

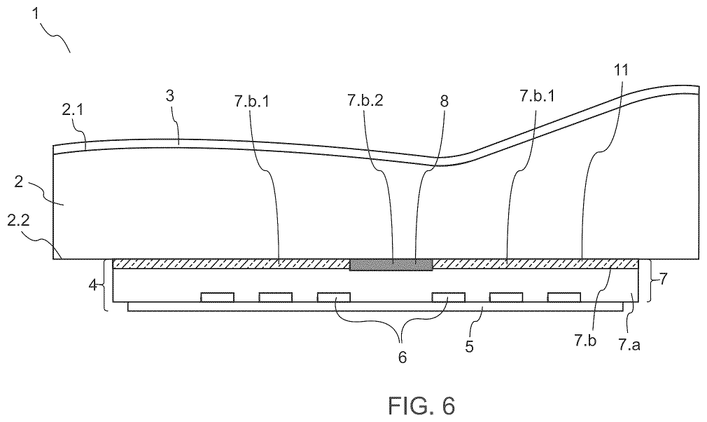

Furthermore, it is possible that at least one of the base body (2), the decorative layer (3) and the adhesive layer (7) has areas in which light-converting particles are arranged. The light-converting particles can be used, for example, to convert light of a first wavelength emitted by the optoelectronic semiconductor components (6) into light of a second wavelength that differs from the first wavelength. FIG. 6 shows by way of example that the functional sublayer (7.b) has light-converting particles (11) in a first subregion (7.b.1). In a second subregion (7.b.2), on the other hand, the functional sublayer (7.b) has light-absorbing particles (8). In particular, the functional sublayer (7.b) in the second subregion (7.b.2) has a high concentration of light-absorbing particles (8), so that the functional sublayer (7.b) in the second subregion (7.b.2) is essentially opaque. The functional sublayer (7.b) can thus be structured and have opaque areas as well as translucent or light-converting areas. The opaque areas are formed in areas of the functional sublayer (7.b) that are not directly in the beam path of an optoelectronic semiconductor component (6). The light-transmitting or light-converting regions, on the other hand, are formed in regions of the functional sublayer (7.b) which lie in the beam path of an optoelectronic semiconductor component (6).

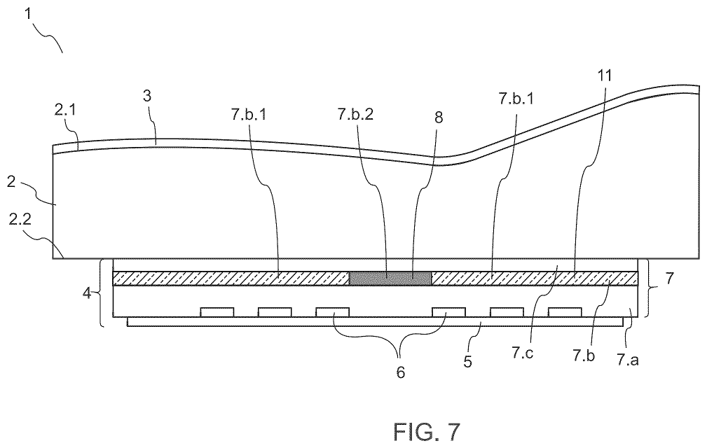

The adhesive layer (7) of the optoelectronic lighting device (1) shown in FIG. 7 has a second sublayer (7.c) in addition to the embodiment example shown in FIG. 6. The second sublayer (7.c) is made of the same material as the first sublayer (7.a) and in particular has transparent and adhesive properties. The functional sublayer (7.b) is arranged between the first sublayer (7.a) and the second sublayer (7.c). Such an arrangement makes it possible to provide a functional sublayer (7.b) in the adhesive layer (7) and still ensure the best possible adhesion of the optoelectronic foil (4) to the second main surface (2.2).

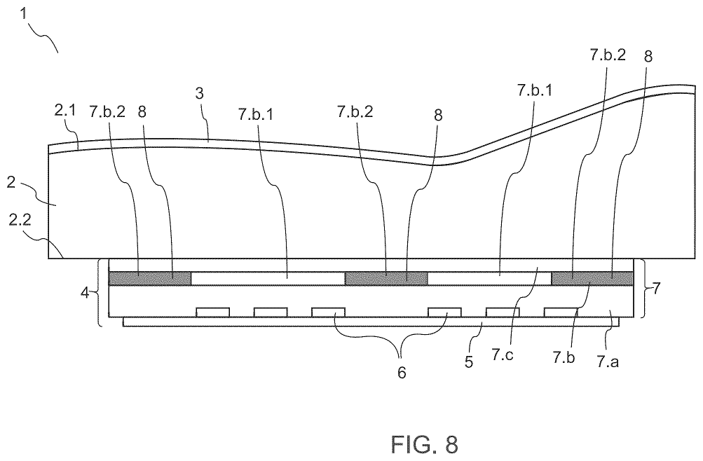

As shown in FIG. 8, the functional sublayer (7.b) can also be designed as a so-called shadow foil and be structured and arranged above the optoelectronic semiconductor components (6) in such a way that first subregions (7.b.1), which are transparent, lie in the beam path of the optoelectronic semiconductor components (6) and second partial regions (7.b.2), which are opaque, are formed in areas of the functional sublayer (7.b), do not lie directly in the beam path of an optoelectronic semiconductor component (6). The advantage of such a structured functional sublayer (7.b) arranged above the optoelectronic semiconductor components (6) is that the contrast of the light emitted by the optoelectronic semiconductor components (6) can be increased as a result.

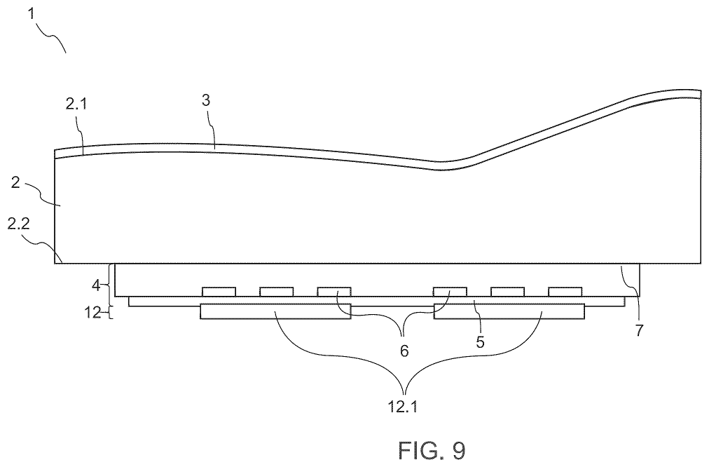

The optoelectronic lighting device (1) shown in FIG. 9 additionally comprises a reflector layer (12), which is arranged on the side of the carrier substrate (5) opposite the base body (2). In the embodiment example shown, the reflector layer (12) is structured and designed in such a way that at least the areas (12.1) of the carrier substrate (5) opposite the optoelectronic semiconductor components (6) are covered by the reflector layer (12). In areas in which, on the other hand, no optoelectronic semiconductor components (6) are arranged on the opposite side of the carrier substrate (5), the reflector layer (12) has recesses. The reflector layer (12) can thus be arranged essentially exclusively below the optoelectronic semiconductor components (6) on the carrier substrate (5).

The reflector layer (12) can, for example, be designed to reflect the light emitted by the optoelectronic semiconductor components (6), which is not emitted in the direction of the base body (2), in the direction of the base body (2). The reflector layer (12) can be applied or printed onto the carrier substrate (5) in the form of a white coating, for example.

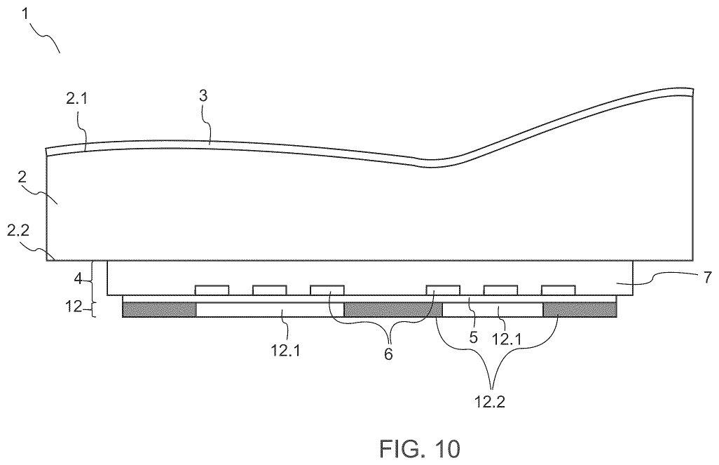

The recesses (12.2) of the reflector layer (12) can be filled with a light-absorbing material as shown in FIG. 10. This makes it possible to increase the contrast of the light emitted by the optoelectronic semiconductor components (6) or the light reflected by the reflector layer (12).

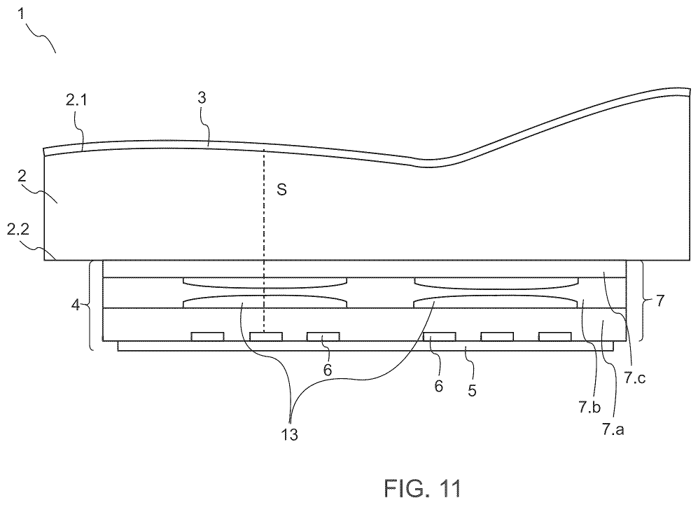

In some embodiments, at least one of the base body (2) and the adhesive layer (7) has Micro structured optics. The Micro structured optics are arranged in particular in the beam path of the optoelectronic semiconductor components (6). As shown as an example in FIG. 11, Micro structured optics (13) can be arranged in the beam path (S) of the optoelectronic semiconductor components (6) in the functional sublayer (7.b), for example. The Micro structured optics (13) are formed by lenses which are encapsulated in the functional sublayer (7.b). The Micro structured optics (13) can, for example, be designed to focus, disperse or direct the light emitted by the optoelectronic semiconductor components (6). For this purpose, they are made of a material with a higher refractive index than the material of the other layers of the adhesive layer (7) and than the material in which the micro-structured optics (13) are encapsulated. In the present case, for example, the light emitted by three optoelectronic semiconductor components (6) is focused and collimated by means of Micro structured optics (13).

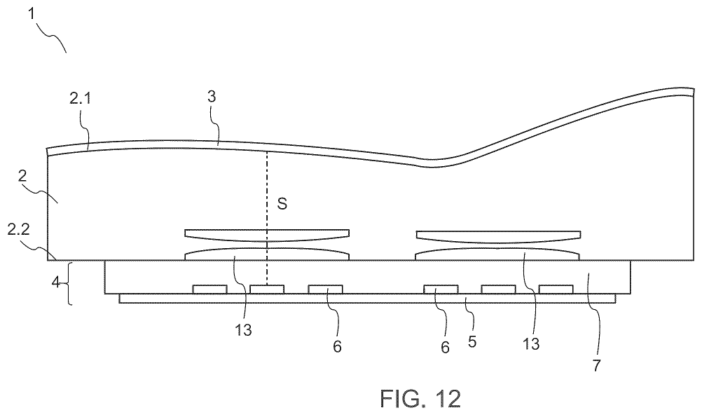

It is also possible for Micro structured optics (13) to be cast in the base body (2), as shown in FIG. 12. The Micro structured optics (13) are made of a material with a higher refractive index than the material of the adhesive layer (7) and than the material of the base body (2). In this case, too, the Micro structured optics are designed as a lens that focuses and collimates the light emitted by three optoelectronic semiconductor components (6) in each case.

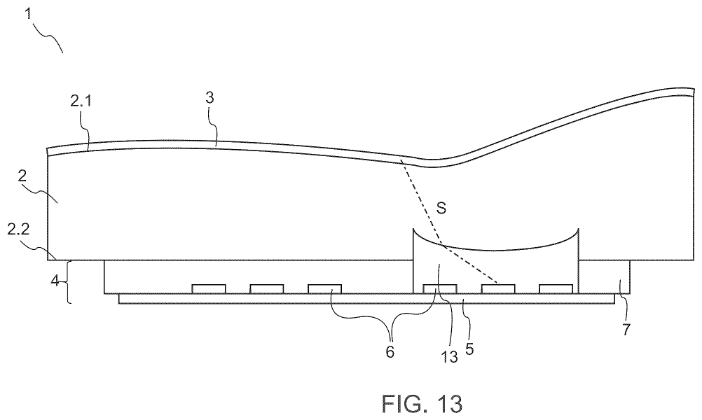

FIG. 13 shows an optoelectronic lighting device (1) comprising a Micro structured optic (13) that extends from the carrier substrate (5) through the adhesive layer (7) into the base body (2). In the present embodiment example, the Micro structured optics (13) is designed as a plano-concave diverging lens. In this context, plano-concave means that the diverging lens has a flat surface and a concave surface opposite the flat surface. The flat surface faces the optoelectronic semiconductor components (6), whereas the concave surface faces away from the optoelectronic semiconductor components (6) in the direction of emission. As shown in the figure, the light of a plurality of optoelectronic semiconductor components (6) or the beams (S) of the light emitted by the plurality of optoelectronic semiconductor components (6) can be directed to desired areas of the decorative layer (3) with such a Micro structured optics (13).

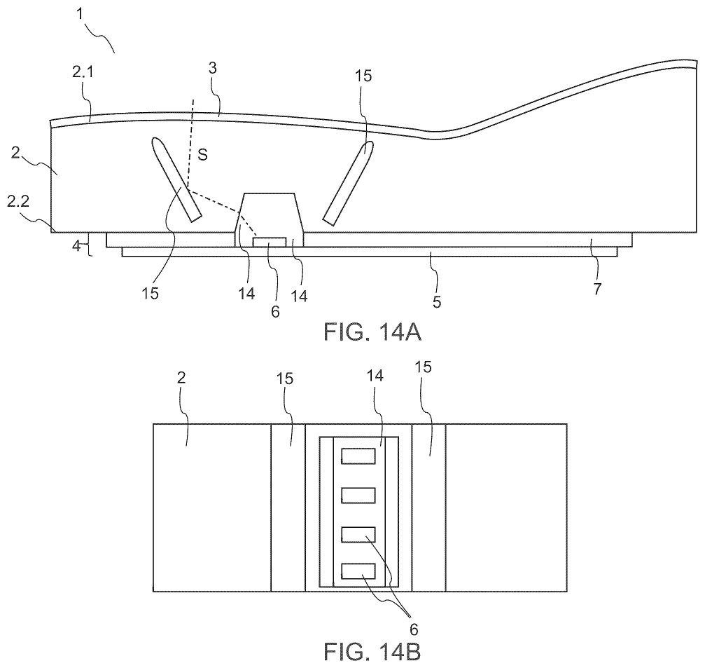

FIGS. 14A and 14B show a sectional view and a top view of an optoelectronic lighting device (1) which has cavities (14) filled with air inside the base body (2) and the adhesive layer (7) and hollow spaces (15) filled with air inside the base body (2). The cavities (14) filled with air and the hollow spaces (15) filled with air together form an optical element. In particular, the cavities (14) filled with air and the hollow spaces (15) filled with air are designed and arranged relative to each other in such a way that they essentially form a lens known as a TIR lens (total internal reflection, TIR). The TIR lens is formed in particular by the fact that the light beams (S) from the optoelectronic semiconductor components (6) are reflected at the interfaces between the cavities (14) filled with air or the hollow spaces (15) filled with air and the adhesive layer (7) or the base body (2) above a critical angle and thus deflected. This allows the light emitted by the optoelectronic semiconductor components (6) to be collimated or deflected.

The air-filled cavities (14, 15) within the base body (2) can, for example, be created by slides in the casting process of the base body (2). FIG. 14B shows that the air-filled hollow spaces (15) within the base body (2) extend over the entire width of the base body (2) and can therefore each be created by a slide that is inserted laterally into the base body (2). The cavity (14) within the adhesive layer (7), on the other hand, can be created by structuring the adhesive layer (7) by removing the material of the adhesive layer (7) in the area of the cavity (14).

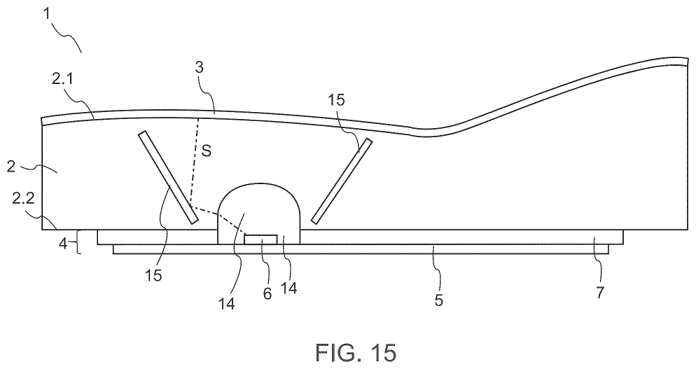

FIG. 15 shows a further embodiment example of an optoelectronic lighting device (1) which has cavities (14) filled with air inside the base body (2) and the adhesive layer (7) and hollow spaces (15) filled with air inside the base body (2). In contrast to the embodiment example shown in FIG. 14A, the cavities (14) filled with air and the hollow spaces (15) filled with air have a different geometry, but also form a TIR lens as in the aforementioned embodiment example. The two embodiment examples are intended to illustrate in particular that the geometry of the hollow spaces (15) filled with air and the cavities (14) filled with air can be selected according to the requirements in such a way that the light emitted by the optoelectronic semiconductor components (6) can be collimated or directed in the desired manner.

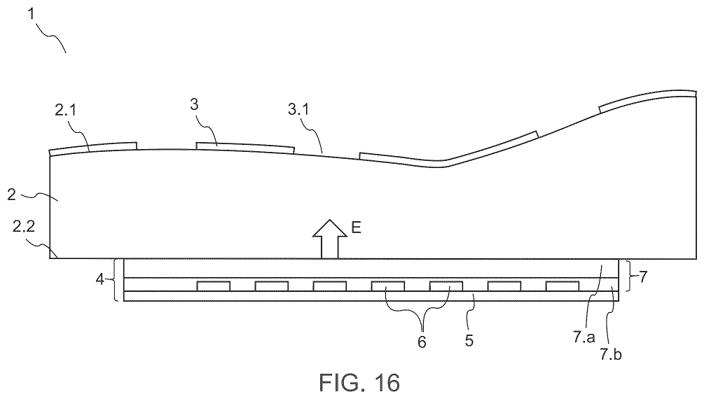

In contrast to the optoelectronic lighting device (1) shown in FIG. 4, the decorative layer (3) of the optoelectronic lighting device (1) shown in FIG. 16 has recesses (3.1). The recesses (3.1) can be formed in particular as the transparent areas of the decorative layer (3) through which the light of the optoelectronic semiconductor components (6) passes to the outside. The recesses (3.1) can, for example, be filled with a transparent material or, as shown in the figure, remain free, i.e. not filled with any material. The decorative layer (3) is structured by the recesses (3.1) and the recesses (3.1) can be arranged relative to one another in such a way that they form a pattern or symbols which are to be illuminated during the intended use of the optoelectronic lighting device (1).

The decorative layer (3) can be formed in particular by a semi-transparent or non-transparent material, so that only the areas of the recesses (3.1) are illuminated during intended use of the optoelectronic lighting device (1). By using a semi-transparent or non-transparent material, the pattern defined by the recesses (3.1) or the symbols defined by the recesses (3.1) can be illuminated or displayed sharply and with a high contrast.

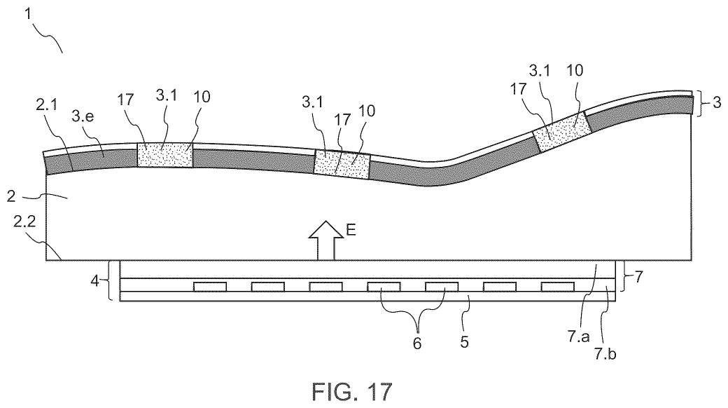

FIG. 17 shows an optoelectronic lighting device (1) whose decorative layer (3) comprises an additional reflective layer (3.e) which is formed adjacent to the base body (2). The recesses (3.1) in the decorative layer (3), which were also described in the previous embodiment example, also extend through the additional reflective layer (3.e) in the present case. The additional reflective layer (3.e) can, for example, be formed by a lacquer printed on the base body (2) or by a structured lacquer arranged on the base body. The reflective layer (3.e) can be used to give the decorative layer (3) a reflective or mirror-like or metallic effect on the outside.

A layer of a semi-transparent or non-transparent material, as described in the previous embodiment example, is also formed on the additional reflective layer (3.e). The recesses (3.1) through the two layers are filled with a material (17) which comprises light-scattering particles (10). The material with the light-scattering particles (10) makes it possible to achieve a homogeneous overall impression of the optoelectronic lighting device (1). The material (17) with the light-scattering particles (10) can be applied, for example, in the form of a 3D coating filled with light-scattering particles (10).

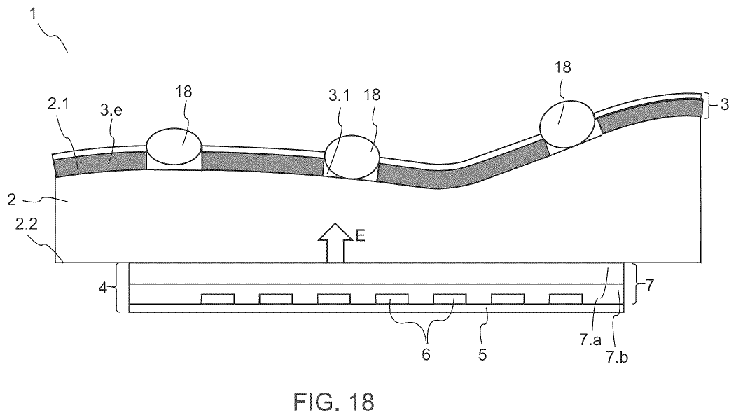

As shown in FIG. 18, however, an optical element (18), in particular in the form of a lens, can also be arranged in each of the recesses (3.1). Such an optical element (18) may, for example, have been applied and produced by means of a 3D lacquer and serve to focus, disperse or direct the light of the optoelectronic semiconductor components (6) emerging from the recesses (3.1) of the decorative layer (3). The optical elements (18) can be flush with the surface of the decorative layer (3) or can protrude beyond the decorative layer (3) as shown in the figure.

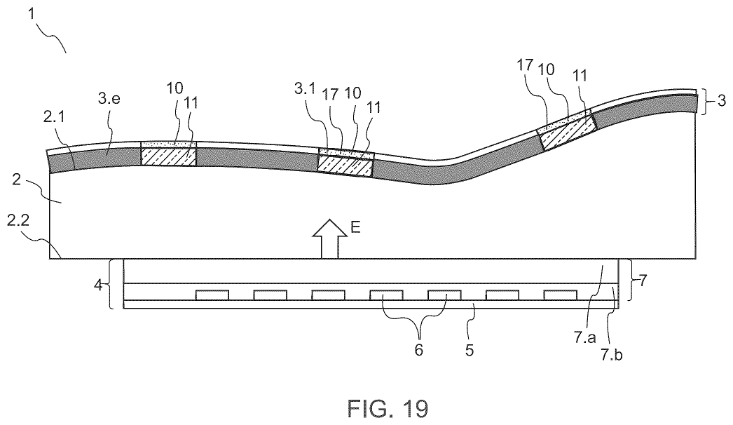

It is also possible that the recesses (3.1), as shown in FIG. 19, are filled with a material (17) which has two layers, of which one layer facing the base body comprises light-converting particles (11) and a layer arranged above it comprises light-scattering particles (10).

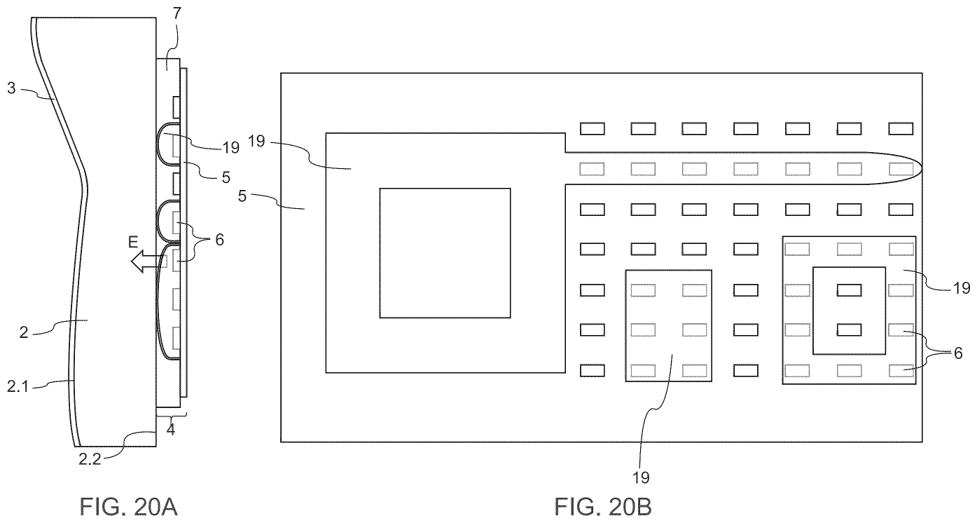

FIG. 20A shows a sectional view of an optoelectronic lighting device (1) comprising several light guides (19) arranged on the carrier substrate (5) or encapsulated in the adhesive layer (7). FIG. 20B shows a top view of the carrier substrate (5) with the light guides (19) arranged thereon. The light guides (19) may have been printed onto the carrier substrate (5), for example using stencil printing, or applied using a dispensing or jetting process. The light guides (19) are arranged on the carrier substrate (5) in such a way that they each cover or enclose a number of the optoelectronic semiconductor components (6). The light emitted by the respective number of optoelectronic semiconductor components (6) can thus propagate in the respective light guide and be distributed along the light guide.

For example, several optoelectronic semiconductor components (6) can be connected by means of an optical fiber and form a symbol or a common surface within a matrix arrangement of several optoelectronic semiconductor components (6). For example, area light sources as well as point light sources can be realized simultaneously within a matrix arrangement of several optoelectronic semiconductor components.

Furthermore, as shown in FIG. 20B, a light guide (19) can enable light to be guided into an area of the optoelectronic lighting device (1) or an area of the carrier substrate (5) in which no optoelectronic semiconductor components (6) are arranged on the carrier substrate (5).

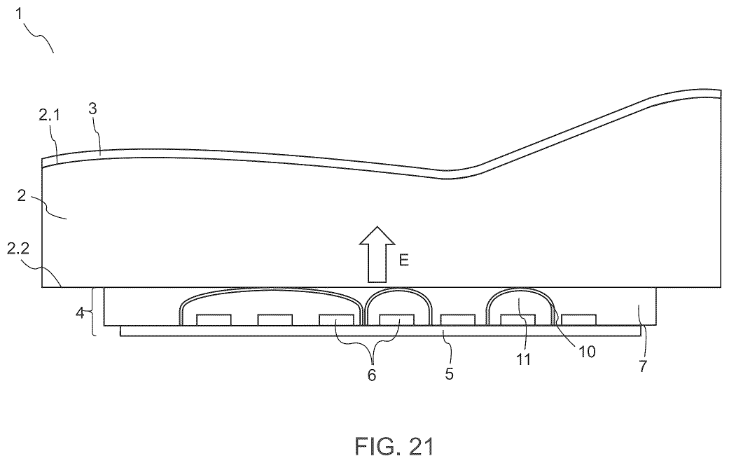

Instead of the light guides, areas can also be printed or applied to the carrier substrate (5) which have light-converting particles (11) and which are coated with a layer which has light-scattering particles (10). An example of such an embodiment is shown in FIG. 21. The areas with the light-converting particles (11) are applied to the carrier substrate (5) in the form of a dome and encapsulated in the adhesive layer (7). Inside these areas are optoelectronic semiconductor components (6) whose emitted light of a first wavelength is converted into light of a second wavelength due to the light-converting particles (11). The layer comprising the light-scattering particles (10) can, for example, have a whitish color impression and be in the form of a so-called “whitish layer”. As a result, for example, light-converting particles (11) that appear colored in the non-illuminated state, such as yellow light-converting particles (11), can be covered by the layer in order to create an overall whitish color impression.

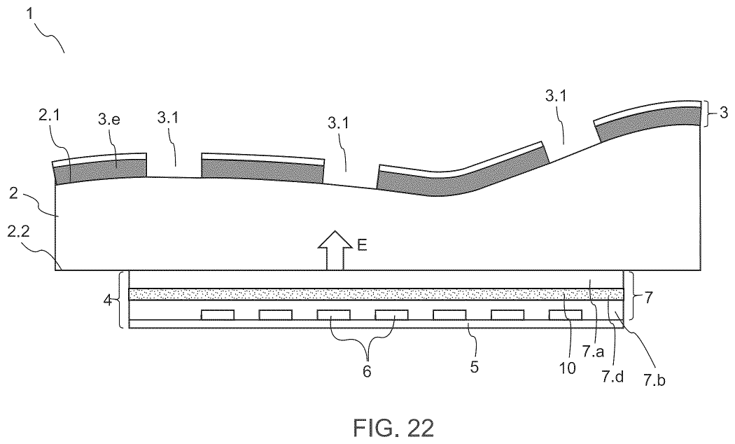

FIG. 22 shows an optoelectronic light-emitting device (1) whose adhesive layer (7) has a further functional sublayer (7.d), which is arranged between the first sublayer (7.a) and the functional sublayer (7.b), in comparison with, for example, the optoelectronic light-emitting device (1) shown in FIG. 17 or 19. In the present example, the further functional sublayer (7.d) comprises light-scattering particles (10) and is designed in particular as a layer which has a whitish color impression. The light-scattering particles (10) can, for example, comprise at least one of the materials AlO₂₃ and TiO₂. In this example, the functional sublayer (7.b) is designed as a light-converting layer and comprises corresponding light-converting particles. Due to the light-converting particles, the functional sublayer (7.b) can, for example, have a colored color impression in the non-illuminated state, such as a yellow color impression due to yellow light-converting particles. However, the whitish further functional sublayer (7.d), which is arranged above the functional sublayer (7.b), can produce a whitish overall color impression in the non-illuminated state of the optoelectronic lighting device (1) in at least those areas that are illuminated in the illuminated state.

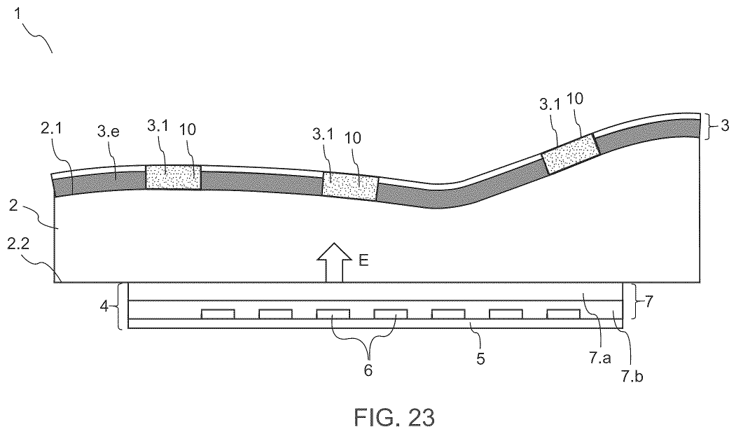

However, as shown in FIG. 23, the light-scattering particles (10) described in the previous embodiment example can also be arranged in the recesses (3.1) of the decorative layer (3). The recesses (3.1) are accordingly filled with a material that has a whitish color impression. This ensures that the optoelectronic lighting device (1) has a whitish overall color impression in the non-illuminated state, at least in the areas that are illuminated in the illuminated state.

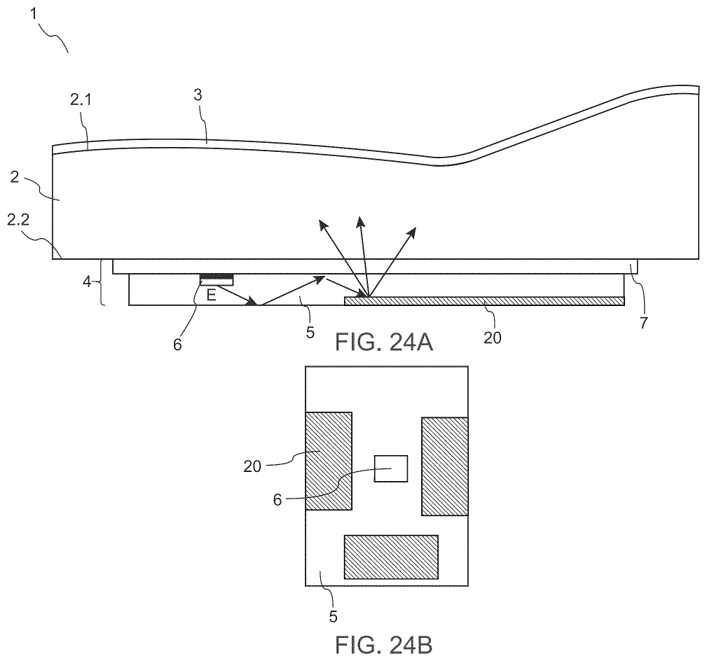

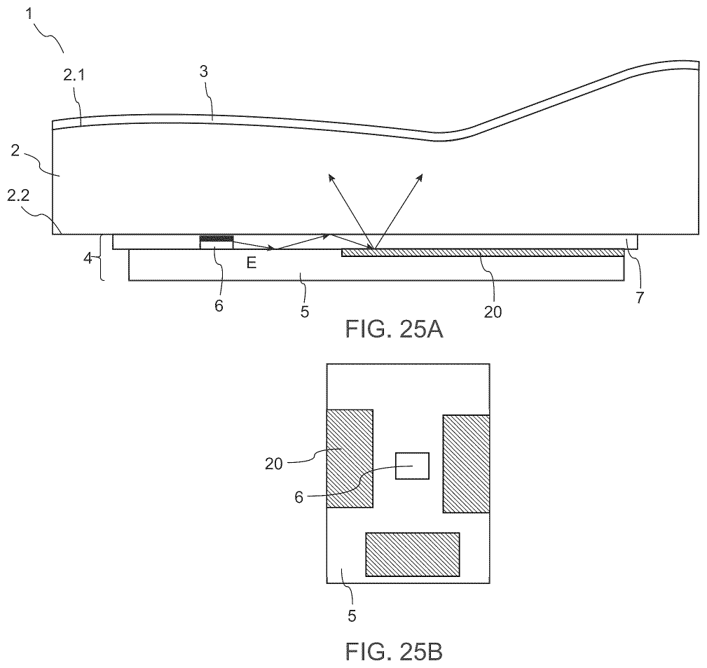

FIGS. 24A and 25A each show a sectional view of a further embodiment example of an optoelectronic lighting device (1) and FIGS. 24B and 25B each show a top view of the respective carrier substrate of the optoelectronic lighting device (1). In contrast to the previous embodiments, however, in the present case the optoelectronic semiconductor components (6) are arranged or formed on the carrier substrate (5) in such a way that their main emission direction (E) does not point in the direction of the base body (2). Although only one optoelectronic semiconductor component (6) is shown as an example in the figures, several optoelectronic semiconductor components (6) can be applied to the carrier substrate (5) in the manner shown.

In the case of the embodiment shown in FIG. 24A, the optoelectronic semiconductor component (6) is in the form of a side-looking emitter or volume emitter which is pressed into or embedded in the carrier substrate (5). In addition to mechanical properties to hold the optoelectronic semiconductor component (6) in position, the carrier substrate (5) has light-conducting properties so that light which is coupled into the carrier substrate by the optoelectronic semiconductor component (6) is guided along the carrier substrate. In order to prevent direct light emission of the semiconductor component (6) in the direction of the base body (2), the optoelectronic semiconductor component (6) has a reflective layer on its upper side facing the base body (2).

The carrier substrate (5) has at least one structured area (20) or, as shown in FIG. 24B, three structured areas (20) for coupling out the light guided in the carrier substrate (5). The light guided in the carrier substrate (5) is scattered at the structured areas (20) and thereby directed in the direction of the base body (2).

The structured regions (20) can be formed on a side of the carrier substrate (5) opposite the base body (2), as shown in FIG. 24A, but the structured regions (20) can also be formed on a side of the carrier substrate (5) facing the base body (2). Similarly, the geometric arrangement of the structured regions (20) around the optoelectronic semiconductor component (6), as shown in FIG. 24B, can also be varied and adapted according to the requirements.

In the case of the embodiment shown in FIG. 25A, the optoelectronic semiconductor component (6) is in the form of a side-looking emitter or edge emitter which is arranged on the carrier substrate (5) and is embedded in the adhesive layer (7). In addition to the adhesive properties for attaching the optoelectronic foil (4) to the second main surface (2.2), the adhesive layer (7) has light-conducting properties, so that light which is coupled from the optoelectronic semiconductor component (6) into the adhesive layer (7) is guided along the adhesive layer (7). As already explained in the previous embodiment example, the optoelectronic semiconductor component (6) has a reflective layer on its upper side facing the base body (2) in order to prevent direct light emission from the semiconductor component (6) in the direction of the base body (2).

The carrier substrate (5) has at least one structured area (20) or, as shown in FIG. 25B, three structured areas (20) for light extraction of the light guided in the adhesive layer (7). The light guided in the adhesive layer (7) is scattered at the structured areas (20) and thereby directed towards the base body (2).

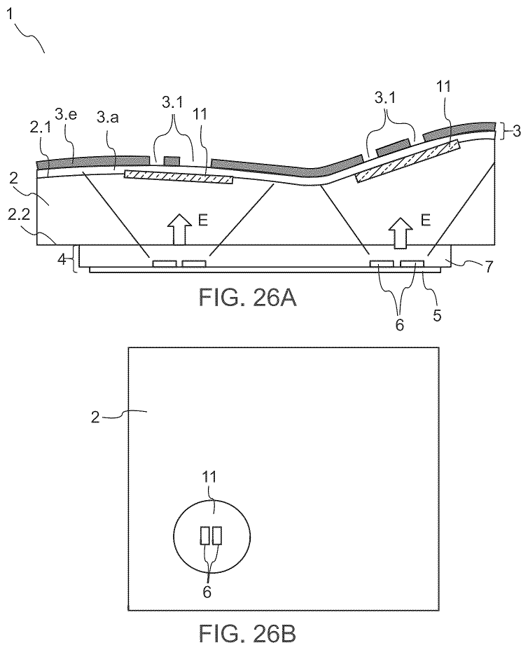

FIG. 26A shows an optoelectronic lighting device (1) which has a structured decorative layer (3). The structured decorative layer (3) has a transparent or diffuse carrier layer (3.a) and a reflective layer (3.e) arranged above the carrier layer (3.a). Recesses (3.1) are formed in the reflective layer (3.e), which are formed or arranged relative to one another in such a way that they form a pattern or symbols which are to be illuminated during intended use of the optoelectronic lighting device (1). On the side of the diffuse carrier layer (3.a) facing away from the reflective layer (3.e), areas comprising light-converting particles (11) are printed at least in the area of the recesses (3.1). The areas comprising light-converting particles (11) can in particular be embedded in the base body (2).

Two optoelectronic semiconductor components (6) are arranged on the carrier layer (5) in the area below the recesses (3.1). The two optoelectronic semiconductor components (6) can, for example, be formed by two LED chips that emit light with a different wavelength. The regions comprising light-converting particles (11) can comprise at least two different types of light-converting particles (11), a first type being designed to convert light of a first wavelength into light of a second wavelength and a second type being designed to convert light of a third wavelength into light of a fourth wavelength. By such an arrangement of optoelectronic semiconductor components (6) and regions with different types of light-converting particles (11) arranged above them, crosstalk between the optoelectronic semiconductor components (6) can be prevented, since different types of light-converting particles (11) are used to convert the light for emitted light with different wavelengths. Furthermore, such an arrangement of optoelectronic semiconductor components (6) and areas with different types of light-converting particles (11) arranged above them can make it easy to mix colors or adjust the color tone by individually adjusting the light intensity emitted by the optoelectronic semiconductor components (6).

In addition to the two optoelectronic semiconductor components (6) shown in the figure and areas with two different types of light-converting particles (11) arranged above them, it is also possible, however, for an area with several different types of light-converting particles (11) to be arranged above several optoelectronic semiconductor components (6) in order to provide an RGB or an RGBW pixel, for example.

FIG. 26B shows a top view of the base body (2) of the optoelectronic lighting device (1) shown in FIG. 26A. It can be seen that the area comprising the light-converting particles (11) is essentially limited to an area above the correspondingly assigned optoelectronic semiconductor components (6) or to an area of the recesses (3.1) of the decorative layer (3).

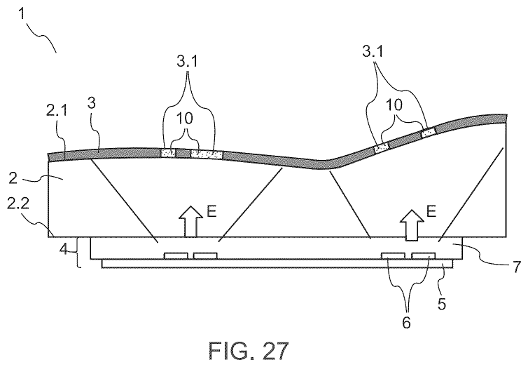

In contrast to the embodiment example shown in FIG. 26A, the decorative layer (3) of the embodiment example shown in FIG. 27 only has a structured reflective or light-absorbing layer, which is arranged on the first main surface (2.1). In contrast to the previous embodiment example, the decorative layer (3) does not have areas printed on it which comprise light-converting particles (11), but the recesses (3.1) are filled with the material comprising the light-converting particles (11) of different types. However, the principle of light conversion of light of different wavelengths is identical to that described in the previous embodiment example.

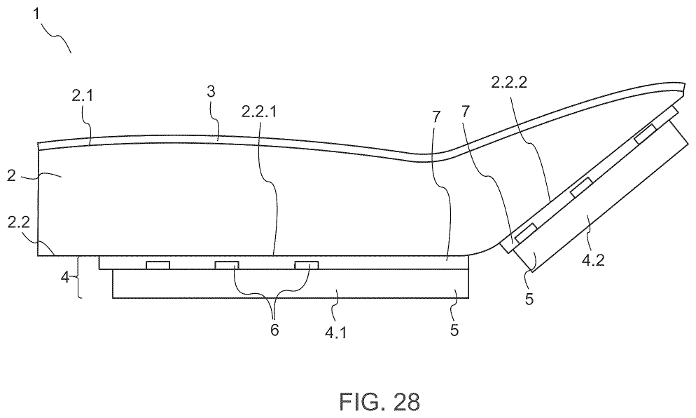

The second main surface (2.2) of the optoelectronic lighting device (1) shown in FIG. 28 has a curvature or kink around an axis that runs perpendicular to the plane of the drawing. The curvature or kink results in a first and a second planar subregion (2.2.1, 2.2.2) of the second main surface (2.2). The optoelectronic foil (4) is further formed by two sub-foils (4.1, 4.2), which are each arranged on the planar subregions (2.2.1, 2.2.2) of the second main surface (2.2). However, the optoelectronic lighting device (1) or the base body (2), the decorative layer (3) and the optoelectronic foil (4) can be formed independently thereof in accordance with at least some of the aforementioned aspects. The exemplary embodiment shown in FIG. 28 is intended to show in particular that, contrary to the illustrations of the preceding embodiments, the second main surface does not necessarily have to be flat, but can also be curved.

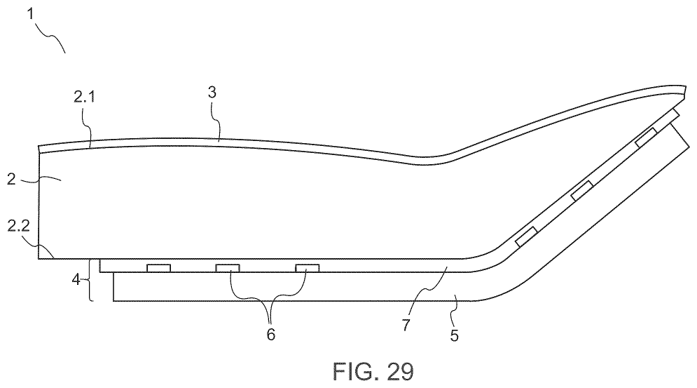

FIG. 29 shows an optoelectronic lighting device (1) in which, as in the previous embodiment example, the second main surface (2.2) has a curvature or kink about an axis that runs perpendicular to the plane of the drawing. In contrast to the embodiment example shown in FIG. 28, however, the optoelectronic foil is not formed by two sub-foils, but is arranged in one piece on the second main surface (2.2). In particular in the event that the second main surface (2.2) comprises partial regions which are flat and are tilted or twisted relative to one another by at most one and the same spatial direction, or that the second main surface has a curvature about only one spatial direction, the optoelectronic foil can be laminated onto the base body simply and only by deforming or bending the foil about this one spatial direction.

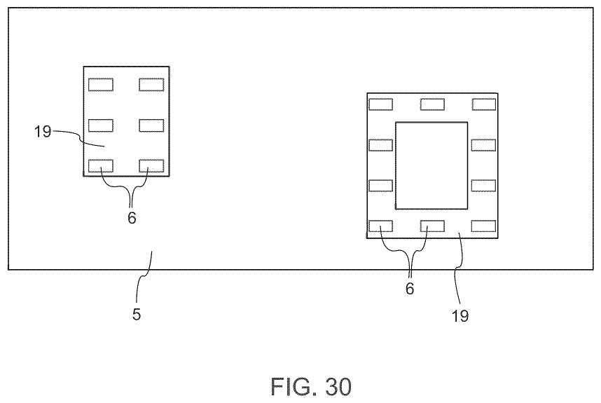

FIG. 30 shows a top view of an optoelectronic foil (4) comprising a plurality of optoelectronic semiconductor components (6). However, the optoelectronic semiconductor components (6) are only arranged in areas of the optoelectronic foil (4) which are to be illuminated during intended use of the optoelectronic lighting device (1). As a result, costs and weight can be saved compared to an optoelectronic foil (4) which has optoelectronic semiconductor components (6) over its entire surface.

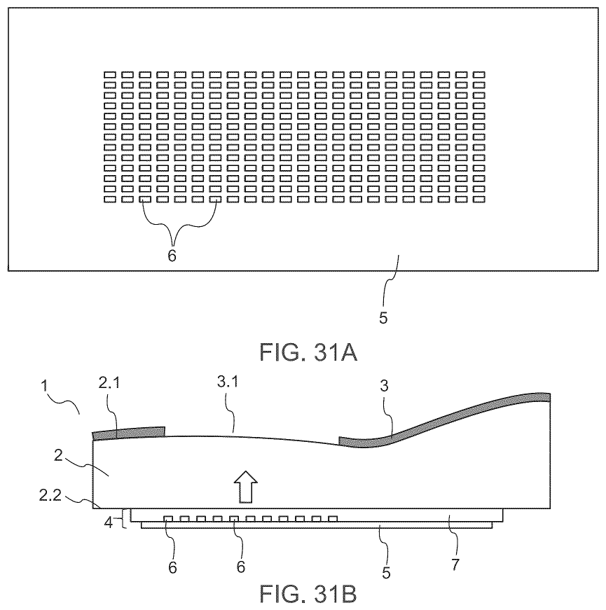

FIGS. 31A and 31B show a top view and a sectional view of an optoelectronic lighting device (1) comprising a matrix arrangement of optoelectronic semiconductor components (6). The semiconductor components (6) are arranged in columns and rows on the carrier substrate (5) and can be individually controlled. Both the base body (2) and the decorative layer (3) are transparent in areas above the matrix or have recesses (3.1) so that the matrix arrangement of optoelectronic semiconductor components (6) can shine through the base body and the decorative layer.

Such a matrix arrangement of optoelectronic semiconductor components (6) can, for example, form a display by means of which information and/or images can be shown on or in the optoelectronic lighting device (1). The optoelectronic lighting device (1) or the base body (2), the decorative layer (3) and the optoelectronic foil (4) can additionally be further formed in accordance with at least some of the aforementioned aspects.

### REFERENCE LIST

1 optoelectronic lighting device
2 base body
2.1 first main surface
2.2 second main surface
2.2.1 first subregion
2.2.2 second subregion
3 decorative layer
3.1 recesses in the decorative layer
3.a diffuse carrier layer
3.b protective layer
3.c first coating
3.d second coating
3.e reflective layer
4 optoelectronic foil
4.1 first sub-foil
4.2 second sub-foil
5 carrier substrate
6 optoelectronic semiconductor component
7 adhesive layer
7.a first sublayer
7.b functional sublayer
7.c second sublayer
7.d further functional sublayer
8 light-absorbing particles
9 protective foil
10 light-scattering particles
11 light-converting particles
12 reflector layer
12.1 regions of the reflector layer
12.2 recesses in the reflector layer
13 structured optics
14 cavity
15 hollow space
16 transparent material
17 material
18 optical element
19 light guide
20 structured area
E emission direction
S beam path, light beams

1. An optoelectronic lighting device comprising:
an at least partially transparent base body with a first main surface, in particular curved surface, and a second main surface opposite the first main surface, wherein the second main surface does at least partially not extend parallel to the first main surface;
a decorative layer arranged on the curved first main surface, which substantially follows the curvature of the first main surface; and
an optoelectronic foil arranged on the second main surface, which comprises:
a carrier substrate, in particular a flexible carrier substrate;
at least one electrical line and a plurality of optoelectronic semiconductor components arranged on the carrier substrate; and
an at least partially transparent adhesive layer, which is arranged between the optoelectronic semiconductor components and the base body and which connects the optoelectronic foil to the second main surface,
wherein the optoelectronic semiconductor components are embedded in the adhesive layer.

2. The optoelectronic lighting device according to claim 1,
wherein a number of the plurality of optoelectronic semiconductor components are arranged in front of at least one transparent region of the base body as viewed in an emission direction of an optoelectronic semiconductor component.

3. The optoelectronic lighting device according to claim 1,
wherein the second main surface also comprises a curvature in at least one spatial direction, and
wherein in particular the optoelectronic foil substantially follows the curvature of the second main surface.

4. The optoelectronic lighting device according to claim 1,
wherein the decorative layer comprises at least partial regions which are transparent.

5. The optoelectronic lighting device according to claim 1,
wherein the adhesive layer comprises at least one of the following materials:
PVB;
EVA;
Thermoplastic polymers;
Silicone;
Acrylic; and
an epoxy.

6. The optoelectronic lighting device according to claim 1,
wherein the adhesive layer is provided with light-absorbing particles.

7. The optoelectronic lighting device according to claim 1,
further comprising a protective foil which covers a side of the optoelectronic foil opposite the base body.

8. The optoelectronic lighting device according to claim 1,
wherein at least one of the base body, the decorative layer and the adhesive layer comprises light-scattering particles and/or
light-converting particles.

9. (canceled)

10. The optoelectronic lighting device according to claim 1,
wherein the adhesive layer comprises a layer sequence of a first sublayer and a functional sublayer.

11. The optoelectronic lighting device according to claim 10,
wherein the optoelectronic semiconductor components are encapsulated in the functional sublayer, or
wherein the functional sublayer is arranged adjacent to the base body, or
wherein the adhesive layer comprises a second sublayer and the functional sublayer is arranged between the first and the second sublayer, and/or
wherein the functional sublayer comprises at least a first subregion in which light-converting and/or light-scattering particles are arranged, and/or
wherein the functional sublayer comprises at least a second subregion in which light-absorbing particles are arranged.

12-15. (canceled)

16. The optoelectronic lighting device according to claim 1,
further comprising a reflector layer, which is arranged on a side of the carrier substrate opposite the base body.

17. The optoelectronic lighting device according to claim 16,
wherein the reflector layer is structured in such a way that it substantially only covers regions of the carrier substrate opposite the optoelectronic semiconductor components.

18. The optoelectronic lighting device according to claim 17, wherein the structured reflector layer comprises light-absorbing regions.

19. The optoelectronic lighting device according to claim 1,
wherein at least one of the base body and the adhesive layer comprises microstructured optics, wherein the micro-structured optics are arranged in particular in the beam path of the optoelectronic semiconductor components; and/or
wherein at least one of the base body and the adhesive layer comprises at least one cavity filled with air and/or at least one hollow space filled with air, wherein the at least one cavity and/or the at least one hollow space are designed and arranged in such a way that they form an optical element, in particular a lens, in the beam path of at least one optoelectronic semiconductor component.

20. (canceled)

21. The optoelectronic lighting device according to claim 1,
wherein the decorative layer is formed by a light-absorbing material and comprises recesses.

22. The optoelectronic lighting device according to claim 21,
wherein the recesses of the decorative layer are filled with a transparent material; and/or
wherein the recesses of the decorative layer are filled with a material which comprises light-scattering and/or light-converting particles; and/or
wherein an optical element, in particular a lens, is arranged in at least one of the recesses; and/or
wherein the decorative layer comprises a reflective layer which is formed adjacent to the base body.

23-25. (canceled)

26. The optoelectronic lighting device according to claim 1,
wherein a light guide is formed in at least one of the base body and the adhesive layer.

27. The optoelectronic lighting device according to claim 1,
wherein at least one of the optoelectronic semiconductor components is formed as an edge-emitting semiconductor chip, and
wherein the carrier substrate comprises a structured area such that light emitted by the edge-emitting semiconductor chip is directed towards the base body.

28-29. (canceled)

30. The optoelectronic lighting device according to claim 1,
wherein the optoelectronic foil is formed by at least two sub-foils, and a first sub-foil is arranged on a first partial region of the second main surface and a second sub-foil is arranged on a second partial region of the second main surface.

31. The optoelectronic lighting device according to claim 1,
wherein the optoelectronic semiconductor components are arranged in a matrix of rows and columns and can be individually controlled.
